(19) United States
(12) Patent Application Publication
(10) Pub. No.: US 2011/0030754 A1
(43) Pub. Date: Feb. 10, 2011

(54) THERMOELECTRIC MODULES AND RELATED METHODS

(75) Inventors: Robert Michael Smythe, Ewing, NJ (US); Jeffrey Gerard Hershberger, Shaker Heights, OH (US); Richard F. Hill, Parkman, OH (US)

Correspondence Address: HARNESS, DICKEY, & PIERCE, P.L.C, 7700 Bonhomme, Suite 400, ST. LOUIS, MO, 63105, US

(73) Assignee: Laird Technologies, Inc., Chesterfield, MO (US)

(21) Appl. No.: 12/560,194

(22) Filed: Sep. 15, 2009

Related U.S. Application Data
(60) Provisional application No. 61/231,939, filed on Aug. 6, 2009.

(51) Int. Cl. H01L 35/02; H01L 35/34

(52) U.S. Cl. 136/233; 29/623.2; 136/201

(57) ABSTRACT

An example thermoelectric module of the present disclosure generally includes a first laminate having a dielectric layer and an electrically conductive layer coupled to the dielectric layer, a second laminate having a dielectric layer and an electrically conductive layer coupled to the dielectric layer, and thermoelectric elements disposed generally between the first and second laminates. At least one of the dielectric layers is a polymeric dielectric layer. The electrically conductive layer of the first laminate is at least partially removed to form electrically conductive pads on the first laminate. The electrically conductive layer of the second laminate is at least partially removed to form electrically conductive pads on the second laminate. The thermoelectric elements are coupled to the electrically conductive pads of the first and second laminates for electrically coupling the thermoelectric elements together.

### CROSS-REFERENCE TO RELATED APPLICATION

This application claims the benefit of U.S. Provisional Application No. 61/231,939, filed on Aug. 6, 2009, the entire disclosure of which is incorporated herein by reference.

### FIELD

The present disclosure relates generally to thermoelectric modules, and more particularly to thermoelectric modules having upper and lower laminates between which thermoelectric elements are positioned, and to methods for making such thermoelectric modules.

### BACKGROUND

This section provides background information related to the present disclosure which is not necessarily prior art.

A thermoelectric module (TEM) is a solid state device that can operate as a heat pump or as an electrical power generator. When a thermoelectric module is used as a heat pump, the thermoelectric module utilizes the Peltier effect to move heat and may then be referred to as a thermoelectric cooler (TEC). When a thermoelectric module is used to generate electricity, the thermoelectric module may be referred to as a thermoelectric generator (TEG). The TEG may be electrically connected to a power storage circuit, such as a battery charger, etc. for storing electricity generated by the TEG.

With regard to use of a thermoelectric module as a TEC, and by way of general background, the Peltier effect refers to the transport of heat that occurs when electrical current passes through a thermoelectric material. Heat is either picked up where electrons enter the material and is deposited where electrons exit the material (as is the case in an N-type thermoelectric material), or heat is deposited where electrons enter the material and is picked up where electrons exit the material (as is the case in a P-type thermoelectric material). As an example, bismuth telluride may be used as a semiconductor material. A TEC is usually constructed by connecting alternating N-type and P-type elements of thermoelectric material (“elements”) electrically in series and mechanically fixing them between two circuit boards, typically constructed from aluminum oxide. The use of an alternating arrangement of N-type and P-type elements causes electricity to flow in one spatial direction in all N-type elements and in the opposite spatial direction in all P-type elements. As a result, when connected to a direct current power source, electrical current causes heat to move from one side of the TEC to the other (e.g., from one circuit board to the other circuit board, etc.). Naturally, this warms one side of the TEC and cools the other side. A typical application exposes the cooler side of the TEC to an object, substance, or environment to be cooled.

### SUMMARY

This section provides a general summary of the disclosure, and is not a comprehensive disclosure of its full scope or all of its features.

Example embodiments of the present disclosure generally relate to thermoelectric modules. In one example embodiment, a thermoelectric module generally includes a first laminate having a polymeric dielectric layer and an electrically conductive layer coupled to the polymeric dielectric layer, a second laminate having a dielectric layer and an electrically conductive layer coupled to the dielectric layer, and thermoelectric elements disposed generally between the first and second laminates. The electrically conductive layer of the first laminate is at least partially removed to form electrically conductive pads on the first laminate. The electrically conductive layer of the second laminate is at least partially removed to form electrically conductive pads on the second laminate. And, the thermoelectric elements are coupled to the electrically conductive pads of the first and second laminates for electrically coupling the thermoelectric elements together.

In another example embodiment, a thermoelectric module generally includes a first laminate having a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers. A second laminate of the thermoelectric module has a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers. Multiple thermoelectric elements are disposed generally between the first and second laminates. The first electrically conductive layer of the first laminate and the first electrically conductive layer of the second laminate are each at least partially removed to form electrically conductive pads on the first and second laminates. The thermoelectric elements are soldered to the electrically conductive pads of the first and second laminates for electrically coupling the thermoelectric elements together.

Example embodiments of the present disclosure also generally relate to methods of making thermoelectric modules. In one example embodiment, a method of making a thermoelectric module generally includes coupling multiple thermoelectric elements to first and second laminates such that the multiple thermoelectric elements are disposed generally between the first and second laminates, wherein the first and second laminates each include an electrically conductive layer coupled to a dielectric layer, and wherein the dielectric layer of the first laminate and/or the dielectric layer of the second laminate is a polymeric dielectric layer, and wherein the multiple thermoelectric elements are coupled to the electrically conductive layers of the first and second laminates.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an upper perspective view of an example thermoelectric module including one or more aspects of the present disclosure;

FIG. 2 is a side elevation view of the thermoelectric module of FIG. 1;

FIG. 3 is a plan view of an inner portion of an upper laminate of the thermoelectric module of FIG. 1;

FIG. 4 is an end elevation view of the upper laminate of FIG. 3;

FIG. 5 an upper plan view of another example thermoelectric module including one or more aspects of the present disclosure and defining subcircuits of the thermoelectric module, and illustrating in broken lines some example buried current paths extending from the subcircuits, and the thermoelectric elements included therein, toward a periphery of a lower laminate of the thermoelectric module;

FIG. 6 is a plan view of an inner portion of the lower laminate of the thermoelectric module of FIG. 5 illustrating electrically conductive pads for use in interconnecting the thermoelectric elements of each of the subcircuits;

FIG. 7 is a plan view of an inner portion of an upper laminate of the thermoelectric module of FIG. 5 illustrating electrically conductive pads for use in interconnecting the thermoelectric elements of each of the subcircuits;

FIG. 8 is a section view taken in a plane including line 8-8 in FIG. 5;

FIG. 9 is the section view of FIG. 8 with thermal vias shown installed; and

FIG. 10 is a side elevation view of another example thermoelectric module including one or more aspects of the present disclosure.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

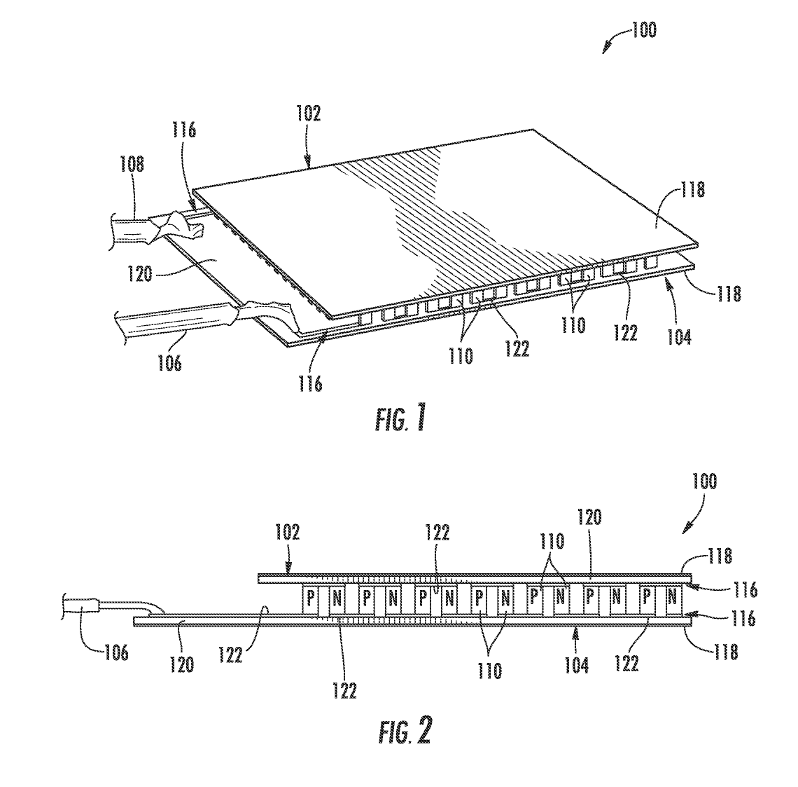

With reference now to the drawings, FIGS. 1-4 illustrate an example embodiment of a thermoelectric module (TEM) 100 including one or more aspects of the present disclosure. The illustrated thermoelectric module 100 can be used, for example, as a heat pump, an electrical power generator, etc. in electrical devices such as, for example, computers, etc., as desired. And, as will be described in more detail hereinafter, the illustrated thermoelectric module 100 provides heat transfer capabilities within the electrical devices as well as electrical insulation to circuits included as part of the thermoelectric module 100.

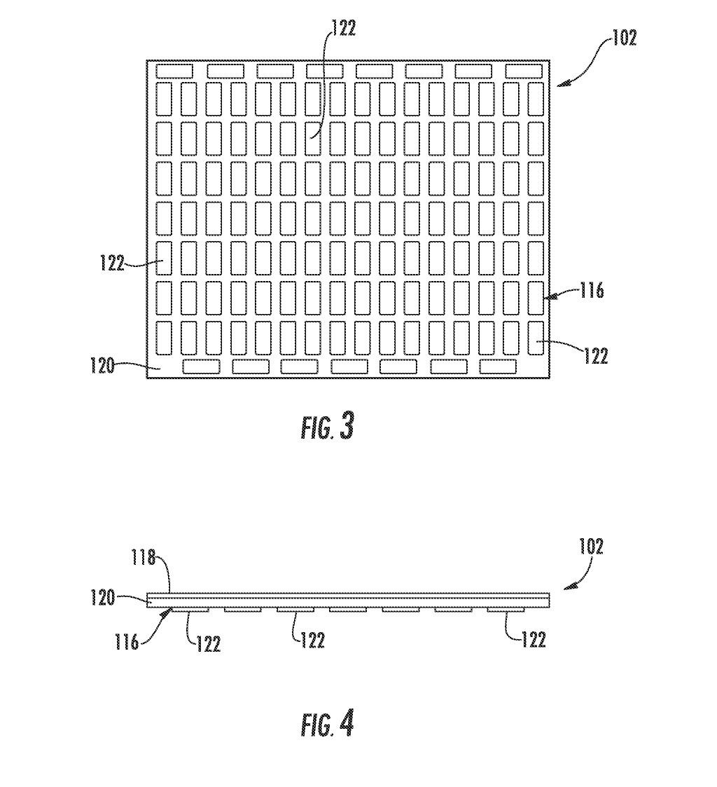

As shown in FIGS. 1 and 2, the illustrated thermoelectric module 100 generally includes a first, upper laminate 102 (broadly, a substrate) and a second, lower laminate 104 (broadly, a substrate) oriented generally parallel to the upper laminate 102 (as viewed in FIGS. 1 and 2). A positive lead wire 106 and a negative lead wire 108 are coupled to the lower laminate 104 for providing power to the thermoelectric module 100 such that the illustrated thermoelectric module 100 generally defines a single circuit. Alternating N-type and P-type thermoelectric elements (each indicated at reference number 110) are disposed generally between the upper and lower laminates 102 and 104. The illustrated N-type and P-type elements 110 are each generally cubic in shape (broadly, cuboid in shape). And, each of the N-type and P-type elements 110 are formed from suitable materials (e.g., bismuth telluride, etc.). In other example embodiments, thermoelectric modules may include configurations of N-type and P-type thermoelectric elements other than alternating configurations (e.g., series configurations, etc.). In addition, thermoelectric elements may have shapes other than cuboid within the scope of the present disclosure.

The upper and lower laminates 102 and 104 of the illustrated thermoelectric module 100 are each generally rectangular in shape. As such, the illustrated thermoelectric module 100 defines a generally rectangular footprint. In addition in the illustrated embodiment, the lower laminate 104 is generally larger than the upper laminate 102 to provide room for coupling the lead wires 106 and 108 to the thermoelectric module 100. In other example embodiments, thermoelectric modules may have substrates with other than rectangular shapes (e.g., circular, oval, square, triangular, etc.) such that they define footprints having other than rectangular shapes and/or may include substrates with different relative sizes than disclosed herein.

In the illustrated embodiment, the upper and lower laminates 102 and 104 each include a layered, laminated, sheet-type construction having a generally rigid structure. In addition, the illustrated upper and lower laminates 102 and 104 are generally prefabricated. For example, the upper and lower laminates 102 may be obtained pre-constructed, and then processed as disclosed herein, for example, for coupling thermoelectric elements 110 therebetween, for use as the thermoelectric module 100, etc. as necessary and/or desired. Example prefabricated laminates suitable for use in the present disclosure include, for example, TLAM circuit boards from Laird Technologies (St. Louis, Mo.), etc. It should be appreciated, however, that laminates could be prefabricated to have any structures and/or combinations of structures as necessary for their desired uses within the scope of the present disclosure.

The illustrated upper laminate 102 is substantially the same as the illustrated lower laminate 104. Therefore, the upper laminate 102 will be described next with it understood that a description of the lower laminate 104 is substantially same. It should be appreciated, however, that in other example embodiments thermoelectric modules may include upper laminates having different configurations (e.g., sizes, shapes, constructions, etc.) from lower laminates. For example, thermoelectric modules may include upper laminates that are prefabricated as generally disclosed herein, and lower laminates that include traditional ceramic constructions, etc.

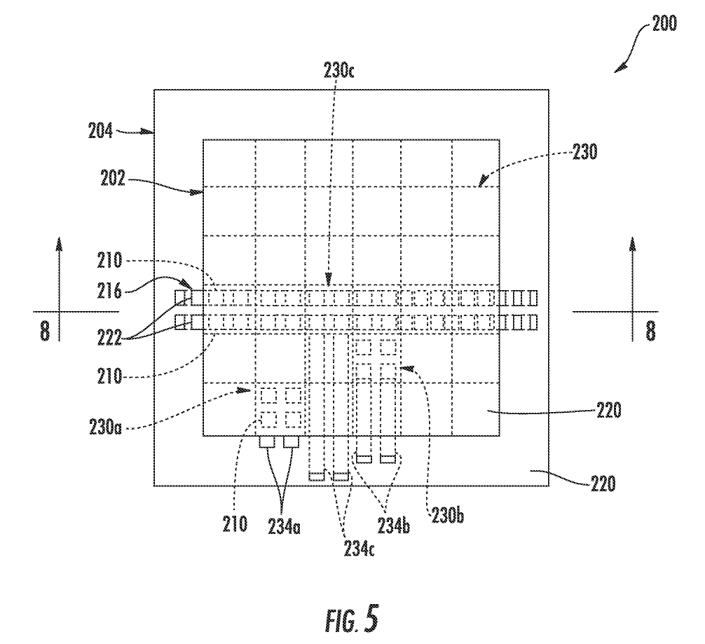

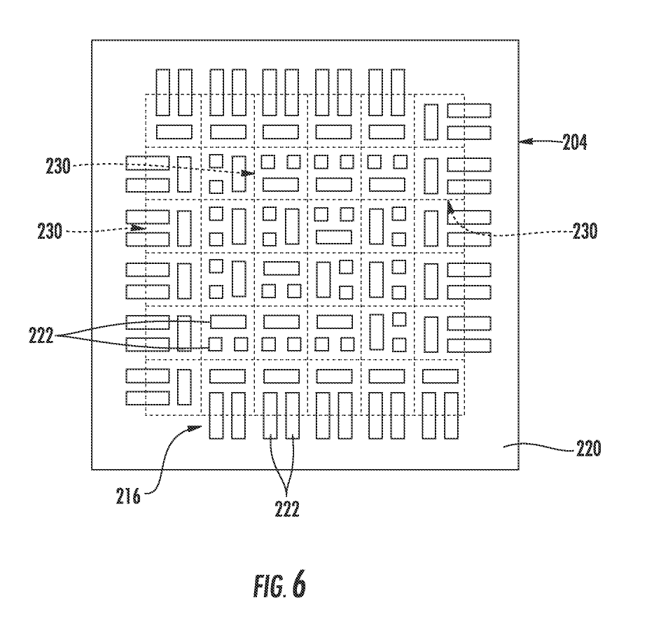

Referring now to FIGS. 3 and 4, the illustrated upper laminate 102 (as generally prefabricated) generally includes a first, inner electrically conductive layer 116 and a second, outer electrically conductive layer 118 (e.g., formed from copper foil, etc.) with a polymeric dielectric layer 120 disposed generally between the inner and outer electrically conductive layers 116 and 118. The inner and outer electrically conductive layers 116 and 118 are coupled to the dielectric layer 120 by suitable processes. For example, the inner and outer electrically conductive layers 116 and 118 may be laminated to, pressed to, etc. the dielectric layer 120.

The inner electrically conductive layer 116 of the illustrated upper laminate 102 is configured to electrically connect the multiple N-type and P-type thermoelectric elements 110 together. For example, at least part of the inner electrically conductive layer 116 of the prefabricated upper laminate 102 is removed (e.g., etched, cut (e.g., milled, water jet cut, eroded, etc.), etc.) from the dielectric layer 120 to define electrically conductive pads 122 (e.g., conducting pads, circuit paths, current paths, etc.) on the prefabricated upper laminate 102 extending across the dielectric layer 120. The electrically conductive pads 122 are configured to electrically couple adjacent N-type and P-type thermoelectric elements 110 together in series for operation of the thermoelectric module 100. The N-type and P-type thermoelectric elements 110 can each be coupled to the electrically conductive pads 122 by suitable operations (e.g., soldering, etc.). The inner electrically conductive layer 116 from which the electrically conductive pads 122 are formed may be constructed from any suitable conducting metallic material such as, for example, copper, nickel, aluminum, stainless steel, combinations thereof, etc. And, any suitable thickness of material may be used for the layer 116 (e.g., six-ounce copper foil, etc.), depending, for example, on desired current capacity, etc.

The outer electrically conductive layer 118 of the illustrated upper laminate 102 (as generally prefabricated) is configured to provide a surface for coupling (e.g., physically coupling such as soldering, thermally coupling, etc.) the thermoelectric module 100 to a desired structure (e.g., within an electrical device, to other thermal components, etc.) and/or to provide stability to the thermoelectric module 100 for handling. The layer 118 may be formed from any suitable conducting metallic material such as, for example, copper, nickel, aluminum, stainless steel, combinations thereof, etc. And, any suitable thickness of material may be used for the layer 118 (e.g., twelve-ounce copper foil, etc.), depending, for example, on desired current capacity, structural stability, use, etc. In some example embodiments of the present disclosure, the outer electrically conductive layer 118 may be substantially removed (e.g., etched, cut (e.g., milled, water jet cut, eroded, etc.), etc.) from the dielectric layer 120 leaving bare dielectric. This can provide, for example, thinner thermoelectric module constructions, etc. And in other example embodiments of the present disclosure, the outer electrically conductive layer 118 may be entirely removed.

The polymeric dielectric layer 120 is configured to electrically insulate circuits included as part of the thermoelectric module 100. The layer 120 may be formed from any suitable electrically insulating material within the scope of the present disclosure. For example, the polymeric dielectric layer 120 may include a cured resin within the scope of the present disclosure (e.g., to provide structural stability to the laminate, rigidity to the laminate, etc.). In this example, the cured resin may be generally brittle, for example, at room temperature, etc. The polymeric dielectric layer 120 may also include one or more additives (e.g., thermally conductive filler particles such as fiberglass, ceramics, etc.) to provide one or more of (or combinations of) enhanced adhesion of the polymeric dielectric layer 120 to the inner and outer electrically conductive layers 116 and 118, enhanced thermal conductivity, enhanced dielectric strength, improved coefficients of thermal expansion, etc. In some example embodiments, polymeric dielectric layers may be cured ceramic-filled dielectric layers that are not flexible at room temperature, but instead are brittle at room temperature and will crack when bent. In various example embodiments, dielectric layers may include thickness dimensions of at least about 0.002 inches (at least about 0.05 millimeters). For example, in one embodiment a dielectric layer includes a thickness dimension of about 0.003 inches (about 0.075 millimeters). And, in another example embodiment, a dielectric layer includes a thickness dimension of about 0.004 inches (about 0.1 millimeters). Dielectric layers may have any other desired thickness within the scope of the present disclosure (e.g., based on voltage requirements, etc.).

In an example operation of the illustrated thermoelectric module 100, the thermoelectric module 100 is electrically connected to one or more direct current (DC) power sources (e.g., three, six, twelve volt power sources, other power sources, etc.) (not shown) via the positive and negative lead wires 106 and 108 and is operated as a thermoelectric cooler. Electrical current passing through the thermoelectric module 100 causes heat to be pumped from one side (e.g., the lower laminate 104, etc.) of the thermoelectric module 100 to the other side (e.g., the upper laminate 102, etc.) of the thermoelectric module 100. Naturally, this creates a warmer side (e.g., the upper laminate 102, etc.) and a cooler side (e.g., the lower laminate 104, etc.) for the thermoelectric module 100 such that objects exposed to the cooler side may subsequently be cooled (e.g., such that heat can be transferred from the cooler side to the warmer side, etc.). While example operation of the illustrated thermoelectric module 100 has been described in connection with a thermoelectric cooler, it should be understood that the illustrated thermoelectric module 100 could also be operated as a thermoelectric generator within the scope of the present disclosure.

FIGS. 5-9 illustrate another example embodiment of a thermoelectric module 200 of the present disclosure. The thermoelectric module 200 of this embodiment is similar to the thermoelectric module 100 previously described and illustrated in FIGS. 1-4. In this embodiment, however, thermoelectric elements 210 are arranged to define multiple subcircuits 230 within the thermoelectric module 200 which allows cooling power to be raised and lowered in different areas separately, and dynamically. To accommodate the multiple subcircuits 230, a lower laminate 204 of the thermoelectric module 200 includes a multilayer circuit assembly for use in connecting lead wires (not shown) to each of the multiple subcircuits 230.

As shown in FIG. 5, the thermoelectric module 200 of this embodiment generally includes an upper laminate 202, the lower laminate 204, and an array of thermoelectric elements 210 (e.g., P-type and N-type thermoelectric elements, etc.) disposed generally between the upper and lower laminates 202 and 204. The thermoelectric elements 210 are arranged in multiple two by two arrays. These arrays define thirty-six electrically independent subcircuits 230 of the thermoelectric module 200. Thus, the illustrated thermoelectric module 200 is essentially a six by six square array of thermoelectric sub-modules (or subcircuits 230), with each sub-module having a two by two square array of thermoelectric elements 210. The six by six square arrays of sub-modules (or subcircuits 230) as well as the two by two arrays of thermoelectric elements 210 are illustrated with broken lines in the drawings. However, only a few example two by two arrays thermoelectric elements 210 are shown as part of subcircuits 230 in FIG. 5. With this said, it should be appreciated that all of the illustrated subcircuits 230 each include a two by two array of thermoelectric elements 210 (even though not illustrated).

The subcircuits 230 can be connected together electrically in series, or in parallel, or in an arbitrary series-parallel combination to thereby cause a desired amount of current to pass through them even if only a single fixed DC power source is provided. Thus, the same current may be passing through all of the subcircuits 230, but it can be adjusted in real time to pump a changing amount of heat with optimum efficiency. This may provide advantages in both cooling and power generation.

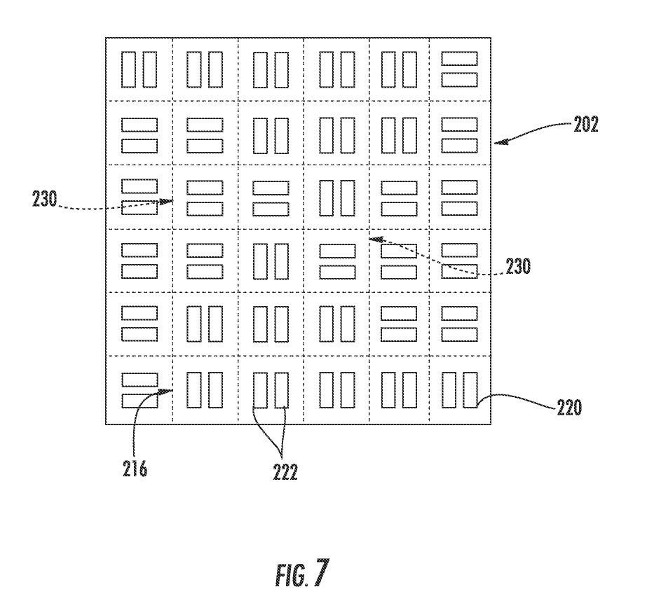

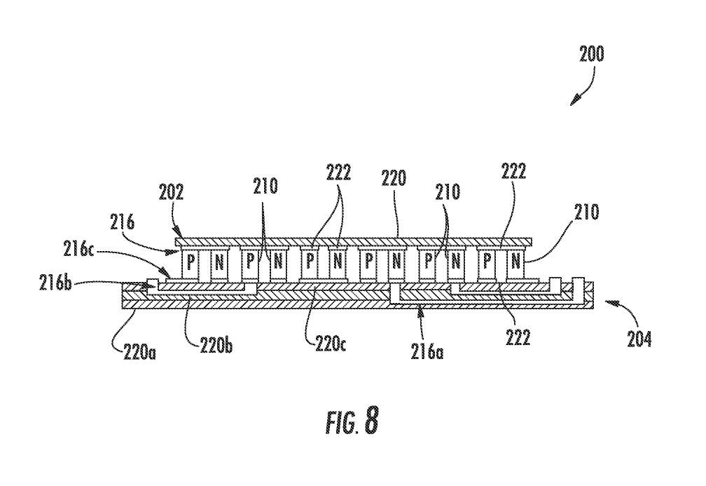

As shown in FIGS. 6 and 7, the lower laminate 204 generally includes (among other layers) an inner electrically conductive layer 216 coupled to a dielectric layer 220. The inner electrically conductive layer 216 is etched to create multiple electrically conductive pads 222 for interconnecting the thermoelectric elements 210 within each subcircuit 230. Similarly, the upper laminate 202 generally includes an inner electrically conductive layer 216 coupled to a dielectric layer 220. The inner electrically conductive layer 216 is etched to create multiple electrically conductive pads 222 for interconnecting the thermoelectric elements 210 within each subcircuit 230. The upper laminate 202 may be a single piece of material, or may be physically divided into thirty-six squares consistent with the six by six array of sub-modules.

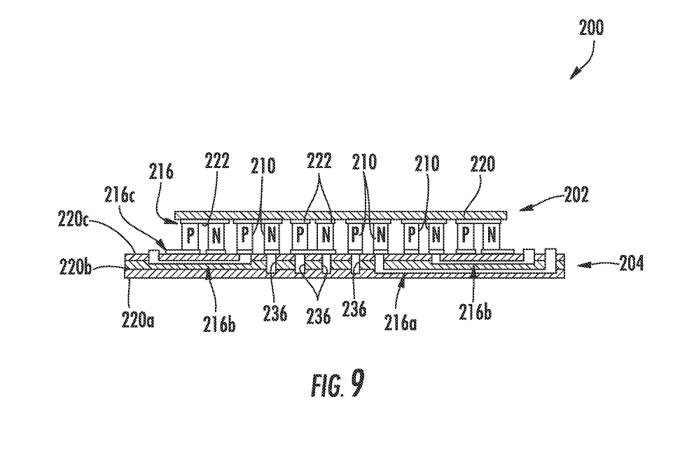

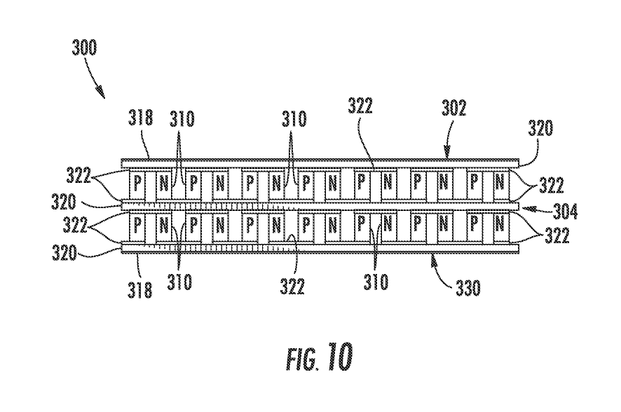

Referring again to FIG. 5, each of the electrically independent subcircuits 230 (e.g., outermost subcircuits 230a and interior subcircuits 230b and 230c, etc.) includes a pair of current paths 234 leading out of the thermoelectric module 200 (e.g., current paths 234a-c leading out of subcircuits 230a-c, etc.). The twenty subcircuits 230 located around the periphery of the thermoelectric module 200 are directly accessible along the edge portions of the thermoelectric module 200 via the current paths 234a (which are generally defined by an upper electrically conductive layer 216a of the lower laminate 204 and thus also include electrically conductive pads 222 (see, e.g., FIGS. 8 and 9, etc.)—this layer is generally indicated at reference number 216 in FIG. 5). However, these current paths 234a generally fill the available space along the edge portions of the thermoelectric module 200. Thus, the current paths 234b and 234c for the interior subcircuits 230b and 230c must be layered within the lower laminate 204 (e.g., buried below the current paths 234a for the outermost subcircuits 230a (see, e.g., FIGS. 8 and 9, etc.), etc.). For example, in FIG. 5 (and FIGS. 8 and 9), current paths 234b for subcircuit 230b are located generally in a middle layer of the lower laminate 204, and current paths 234c for subcircuit 230c are located generally in a lower layer of the lower laminate 204. This will be described in more detail next.

With reference now to FIG. 8, and as previously described, the lower laminate 204 of the illustrated thermoelectric module 200 includes a generally layered construction having six layers. This generally includes lower, middle, and upper conductive layers 216a-c (or circuit layers, or current paths, etc.) and lower, middle, and upper dielectric layers 220a-c. The dielectric layers 220a-c are provided generally between the conductive layers 216a-c, for example, for insulating the thermoelectric module 200 from the environment, for insulating different conductive layers 216a-c, etc. The conductive layers 216a-c are provided for making electrical connections with the thermoelectric elements 210. Current paths 234 (e.g., current paths 234a-c in FIG. 5, etc.) are generally defined by (and are generally included as part of) the respective conductive layers 216a-c in FIG. 8 and are made, for example, by successive operations of coupling conductive layer 216a to dielectric layer 220a, etching the conductive layer 216a to produce current path 234a (FIG. 5), coupling dielectric layer 220b to the remaining portion of conductive layer 216a (e.g., current patch 234a, etc.) (as illustrated in FIG. 8, the dielectric layer 220b may fill in the areas where conductive layer 216a is etched away), coupling conductive layer 216b to dielectric layer 220b, etching the conductive layer 216b to produce current path 234b (FIG. 5), coupling dielectric layer 220c to the remaining portion conductive layer 216b (e.g., current patch 234b, etc.) (as illustrated in FIG. 8, the dielectric layer 220c may fill in the areas where conductive layer 216b is etched away), coupling conductive layer 216c to dielectric layer 220c, and etching the conductive layer 216c to produce current path 234c (FIG. 5) (which also define electrically conductive pads 222).

It should be appreciated that there are some areas in the lower laminate 204 with three layers of dielectric material but no buried current paths (or buried conductive layers), for example, below the thermoelectric elements 210 toward a center of the thermoelectric module 200. Buried current paths are only required in certain areas in the thermoelectric module 200, and are etched away from the dielectric layers 220a-c where not needed. However, thermal conductivity of the dielectric layers 220a-c is not as good as that of the conductive layers 216a-c. Therefore, as shown in FIG. 9, thermal vias 236 may be added to the lower laminate 204 to help improve heat transfer through the lower laminate 204. The thermal vias 236 are formed by making holes through the upper and middle dielectric layers 220c and 220b, and filling the holes with metal (e.g., through a chemical deposition process, etc.). The thermal vias 236 may extend up to the lower dielectric layer 220a, or the vias may extend partially into (but not through) the lower dielectric layer 220a. The lower dielectric layer 220a is left substantially intact in order to electrically isolate the thermal vias 236 from the surrounding environment as the metal in the thermal vias 236 would conduct electricity as well as heat. Alternatively, the upper dielectric layer 220c could be left intact to isolate the thermal vias, and the thermal vias could be formed through the middle and lower dielectric layers 220b and 220a. The thermal vias 236 are positioned, sized, and shaped as appropriate to transport heat between the surrounding environment and one end of a thermoelectric element 210.

In this example embodiment, the layered construction of the lower laminate 204 may also allow for including sensors or other components therein as desired. In addition, the lower laminate 204 may include attachment points for controllers (e.g. chip socket, etc.) and/or edge connectors for external controllers.

FIG. 10 illustrates another example embodiment of a thermoelectric module 300 of the present disclosure. In this example embodiment, the thermoelectric module 300 is a multistage thermoelectric module with multiple cascading laminates (e.g., 302, 304, and 330, etc.) For example, the illustrated multistage thermoelectric module 300 generally includes a first laminate 302, a second laminate 304, and a third laminate 330. Multiple thermoelectric elements 310 are disposed between the first and second laminates 302 and 304 and between the second and third laminates 304 and 330 (such that the second laminate 304 is disposed generally between the first and third laminates 302 and 330). The first laminate 302 generally includes a dielectric layer 320 and a layer 322 of electrically conductive material. The second laminate 304 generally includes a dielectric layer 320, and two layers 322 of electrically conductive material. And, the third laminate 330 generally includes a dielectric layer 320 and a layer 322 of electrically conductive material. The dielectric layer 320 of at least one of the first, second, and third laminates 302, 304, and 330 is a polymeric dielectric layer. The layers 322 of electrically conductive material of the first, second, and third laminates 302, 304, and 330 are each etched to form electrically conductive pads (also indicated at reference numeral 322) for electrically coupling the thermoelectric elements 310 together between the first and second laminates 302 and 304 and between the second and third laminates 304 and 330. In the illustrated thermoelectric module 300, the first and third laminates 302 and 330 also include outer electrically conductive layers 318. In other example embodiments, multistage thermoelectric modules may include more than three laminates with multiple thermoelectric elements disposed between each of the laminates within the scope of the present disclosure.

In another example embodiment of the present disclosure, a thermoelectric module generally includes an upper laminate, a lower laminate, and multiple thermoelectric elements disposed therebetween. The upper laminate generally includes a polymeric dielectric layer and inner and outer layers of copper (or other suitable material). And, the lower laminate generally includes a traditional ceramic dielectric layer and an inner layer of electrically conductive pads. The inner layer of copper of the upper laminate is etched to form electrically conductive pads on the first laminate. The thermoelectric elements are coupled to the electrically conductive pads of the upper laminate and the electrically conductive pads of the lower laminate for electrically coupling the thermoelectric elements together.

In another example embodiment of the present disclosure, a thermoelectric module generally includes a prefabricated upper laminate, a prefabricated lower laminate, and multiple thermoelectric elements disposed therebetween. The prefabricated upper laminate generally includes a polymeric dielectric layer and inner and outer layers of copper. And, the prefabricated lower laminate generally includes a polymeric dielectric layer, an inner layer of copper, and an outer layer of aluminum. The inner layers of copper of each of the upper and lower prefabricated laminates are etched to form electrically conductive pads on the first and second prefabricated laminates from the inner copper layers remaining on the first and second prefabricated laminates for electrically coupling the thermoelectric elements together. And, the outer aluminum layer of the lower prefabricated laminate is shaped with grooves (e.g., corrugated, etc.) to provide structure for receiving thermal interface materials when coupling the thermoelectric module to additional components and/or additional structural rigidity to the laminate. The inner layer of copper of the upper prefabricated laminate and/or the inner layer of copper of the lower prefabricated laminate may have a thickness dimension ranging from about 0.001 inches (about 0.035 millimeters) to about 0.008 inches (about 0.203 millimeters). And, the outer aluminum layer of the lower prefabricated laminate may have a thickness dimension ranging from about 0.04 inches (about 1.02 millimeters) to about 0.062 inches (about 1.575 millimeters).

In still another example embodiment of the present disclosure, a thermoelectric module generally includes an upper laminate, a lower laminate, and multiple thermoelectric elements disposed therebetween. Each of the upper and lower laminates generally include a polymeric dielectric layer and an inner layer of copper. The inner layers of copper of each of the upper and lower laminates are etched to form electrically conductive pads for electrically coupling the thermoelectric elements together. A release liner is coupled by suitable operations to an outer surface of the upper and/or lower laminate (e.g., to an outer surface of the dielectric layer of the upper and/or lower laminate in place of or instead of a metallic layer, etc.). The release liner can then be removed by an ultimate consumer of the thermoelectric module to provide a module with bare dielectric on the outside for subsequent use (without having to etch off an entire layer of metallic material).

In another example embodiment of the present disclosure, a thermoelectric module generally includes a prefabricated upper laminate, a prefabricated lower laminate, and multiple thermoelectric elements disposed therebetween. The upper laminate generally includes a polymeric dielectric layer and inner and outer layers of copper (or other suitable material). And, the lower laminate generally includes a polymeric dielectric layer and inner and outer layers of copper (or other suitable material). The inner layers of copper of each of the upper and lower laminates are etched to form electrically conductive pads for electrically coupling the thermoelectric elements together between the upper and lower laminates. And, the outer layer of copper of the upper laminate and/or the outer layer of copper of the lower laminate may be etched to form electrically conductive pads configured for electrically coupling (e.g., soldering, etc.) the thermoelectric module to an external component. Thus, the outer copper layer of the upper and/or lower laminate (as etched) could provide thermally conductive but separate, isolated circuits for carrying current between the external component and the thermoelectric module.

In another example embodiment of the present disclosure, a thermoelectric module generally includes a prefabricated upper laminate, a prefabricated lower laminate, and multiple thermoelectric elements disposed therebetween. The prefabricated upper laminate generally includes a polymeric dielectric layer and an inner layer of copper (or other suitable material). And, the prefabricated lower laminate generally includes a polymeric dielectric layer and an inner layer of copper (or other suitable material). The inner layers of copper of each of the prefabricated upper and lower laminates are etched to form electrically conductive pads on the prefabricated laminates from the inner copper layers remaining on the prefabricated laminates for electrically coupling the thermoelectric elements together between the prefabricated upper and lower laminates. The outer layers of at least one of the prefabricated upper and lower laminates may be bare leaving exposed dielectric material (such that the laminate is prefabricated, or premade, to have a generally bare outer layer leaving at least part of the dielectric material exposed).

In a further example embodiment of the present disclosure, a method of making a thermoelectric module generally includes coupling (e.g., soldering, etc.) multiple thermoelectric elements to upper and lower prefabricated laminates such that the multiple thermoelectric elements are disposed generally between the upper and lower prefabricated laminates. The upper and lower prefabricated laminates each generally include a first, inner electrically conductive layer (e.g., copper, nickel, combinations thereof, etc.) and a second, outer electrically conductive layer (e.g., copper, aluminum, combinations thereof, etc.) coupled to a polymeric dielectric layer. At least part of the inner electrically conductive layers are removed to form electrically conductive pads to which the multiple thermoelectric elements are coupled. The example method may further include substantially removing the outer electrically conductive layer from the upper and/or lower prefabricated laminates.

It should now be appreciated that thermoelectric modules of the present disclosure may provide one or more various advantages over traditional ceramic based thermoelectric modules. For example, thermoelectric modules of the present disclosure may provide one or more of relatively low cost solutions to cooling operations; may reduce lead time for producing new circuit board designs; may allow for constructing thermoelectric modules having decreased thickness dimensions (e.g., down to about 0.04 inches (about 1 millimeter), etc.); may allow for quicker prototyping; may provide thermoelectric modules having improved strength; may provide improved thermal cycling reliability as the low mechanical stiffness of bare dielectric does not impart thermal expansion stresses to thermoelectric elements of the thermoelectric modules; may provide improved surfaces for coupling other thermal components to the thermoelectric modules; may allow greater varieties of bus bar configurations; and/or may allow for making a thermoelectric module with subcircuits such that the subcircuits can be connected together electrically in series, in parallel, or in an arbitrary series-parallel combination to cause a desired amount of current to pass through them even if only a single fixed DC power source (e.g., voltage, etc.) is provided (e.g., the same current may be passing through all of the subcircuits, but it can be adjusted in real time to pump a changing amount of heat with optimum efficiency such that advantages in both cooling and power generation may be provided, etc.).

Specific dimensions disclosed herein are example in nature and do not limit the scope of the present disclosure.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A thermoelectric module comprising:
a first laminate having a polymeric dielectric layer and an electrically conductive layer coupled to the polymeric dielectric layer;
a second laminate having a dielectric layer and an electrically conductive layer coupled to the dielectric layer; and
thermoelectric elements disposed generally between the first and second laminates;
wherein the electrically conductive layer of the first laminate is at least partially removed to form electrically conductive pads on the first laminate; and
wherein the electrically conductive layer of the second laminate is at least partially removed to form electrically conductive pads on the second laminate; and
wherein the thermoelectric elements are coupled to the electrically conductive pads of the first and second laminates for electrically coupling the thermoelectric elements together.

2. The thermoelectric module of claim 1, wherein the dielectric layer of the second laminate includes a polymeric dielectric layer.

3. The thermoelectric module of claim 1, wherein the dielectric layer of the second laminate is a ceramic dielectric layer.

4. The thermoelectric module of claim 1, wherein the first laminate is prefabricated and/or the second laminate is prefabricated.

5. The thermoelectric module of claim 1, wherein the dielectric layer of the first laminate and/or the dielectric layer of the second laminate has a thickness dimension of at least about 0.002 inches (at least about 0.05 millimeters).

6. The thermoelectric module of claim 1, wherein the first laminate includes a multilayer circuit and/or the second laminate includes a multilayer circuit.

7. The thermoelectric module of claim 6, wherein the first laminate and/or the second laminate includes one or more thermal vias.

8. The thermoelectric module of claim 6, wherein the thermoelectric elements are electrically coupled to form two or more electrically independent subcircuits, each subcircuit being coupled to a separate circuit in said multilayer circuit of the first and or second laminate.

9. The thermoelectric module of claim 1, wherein the polymeric dielectric layer of the first laminate and/or the dielectric layer of the second laminate includes one or more additives to provide one or more of enhanced adhesion of the dielectric layer to the electrically conductive layer, enhanced thermal conductivity, and enhanced dielectric strength.

10. The thermoelectric module of claim 9, wherein the one or more additives include thermally conductive filler particles.

11. The thermoelectric module of claim 1, wherein the first and/or second laminate is generally structurally rigid.

12. The thermoelectric module of claim 1, wherein the polymeric dielectric layer of the first laminate is cured when forming the first laminate and/or the dielectric layer of the second laminate is cured when forming the second laminate.

13. The thermoelectric module of claim 1, wherein the electrically conductive layer of the first laminate is a first electrically conductive layer, the first laminate being prefabricated to include:
the first electrically conductive layer;
the polymeric dielectric layer; and
a second electrically conductive layer;
wherein said polymeric dielectric layer is disposed generally between said first and second electrically conductive layers; and
wherein the second electrically conductive layer is substantially removed from the prefabricated first laminate.

14. The thermoelectric module of claim 13, wherein the second electrically conductive layer of the prefabricated first laminate is one of copper and/or aluminum.

15. The thermoelectric module of claim 13, wherein the second electrically conductive layer of the prefabricated first laminate is entirely removed from the first laminate.

16. The thermoelectric module of claim 1, wherein the electrically conductive layer of the first laminate is a first electrically conductive layer, the first laminate further having a second electrically conductive layer coupled to the polymeric dielectric layer of the first laminate such that said polymeric dielectric layer is disposed generally between said first and second electrically conductive layers.

17. The thermoelectric module of claim 16, wherein the first electrically conductive layer of the first laminate is copper, and wherein the second electrically conductive layer of the first laminate is one of copper and/or aluminum and/or nickel and/or stainless steel.

18. The thermoelectric module of claim 16, wherein the electrically conductive layer of the second laminate is a first electrically conductive layer, the second laminate further having a second electrically conductive layer coupled to the dielectric layer of the second laminate such that said dielectric layer is disposed generally between said first and second electrically conductive layers.

19. The thermoelectric module of claim 1, wherein the electrically conductive layer of the first laminate is at least partially etched and/or cut to form the electrically conductive pads on the first laminate.

20. The thermoelectric module of claim 1, further comprising:
a third laminate having a dielectric layer and an electrically conductive layer coupled to the dielectric layer; and
thermoelectric elements coupled to the third laminate;
wherein the electrically conductive layer of the third laminate is at least partially removed to form electrically conductive pads on the third laminate; and
wherein the thermoelectric elements are coupled to the electrically conductive pads of the third laminate for electrically coupling the thermoelectric elements together.

21. An electronic device including the thermoelectric module of claim 1.

22. A method of making a thermoelectric module, the method comprising coupling multiple thermoelectric elements to first and second laminates such that the multiple thermoelectric elements are disposed generally between the first and second laminates, wherein the first and second laminates each include an electrically conductive layer coupled to a dielectric layer, and wherein the dielectric layer of the first laminate and/or the dielectric layer of the second laminate is a polymeric dielectric layer, and wherein the multiple thermoelectric elements are coupled to the electrically conductive layers of the first and second laminates.

23. The method of claim 22, further comprising etching and/or cutting at least part of the electrically conductive layers of the first and second laminates to form electrically conductive pads on the first and second laminates for electrically coupling the multiple thermoelectric elements together.

24. The method of claim 23, wherein coupling the multiple thermoelectric elements to the first and second laminates includes soldering the multiple thermoelectric elements to the electrically conductive pads of each of the first and second laminates.

25. The method of claim 22, wherein the electrically conductive layer of the first laminate is a first electrically conductive layer, the first laminate further comprising a second electrically conductive layer coupled to the dielectric layer of the first laminate such that said dielectric layer is disposed generally between said first and second electrically conductive layers, the method further comprising substantially removing the second electrically conductive layer from the first laminate.

26. The method of claim 25, wherein the first and/or second electrically conductive layers of the first laminate comprise copper and/or aluminum.

27. The method of claim 22, further comprising coupling the thermoelectric module to an electronic device.

28. A thermoelectric module comprising:
a first laminate having a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers;
a second laminate having a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers; and
multiple thermoelectric elements disposed generally between the first and second laminates;
wherein the first electrically conductive layer of the first laminate and the first electrically conductive layer of the second laminate are each at least partially removed to form electrically conductive pads on the first and second laminates, the thermoelectric elements being soldered to the electrically conductive pads of the first and second laminates for electrically coupling the thermoelectric elements together.

29. The thermoelectric module of claim 28, wherein the second electrically conductive layer of the first laminate is substantially removed from the first laminate and/or the second electrically conductive layer of the second laminate is substantially removed from the second laminate.

30. The thermoelectric module of claim 29, wherein the second electrically conductive layer of the first laminate is entirely removed from the first laminate and/or the second electrically conductive layer of the second laminate is entirely removed from the second laminate.

31. The thermoelectric module of claim 29, wherein the first and/or second electrically conductive layers of the first and/or second laminates comprise copper and/or aluminum.

32. The thermoelectric module of claim 28, further comprising:
a third laminate having a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers; and
multiple thermoelectric elements disposed generally between the second and third laminates;
wherein the second electrically conductive layer of the second laminate and the first electrically conductive layer of the third laminate are each at least partially removed to form electrically conductive pads on the second and third laminates, the thermoelectric elements being soldered to the electrically conductive pads of the second and third laminates for electrically coupling the thermoelectric elements together.
